(19) United States
(12) Patent Application Publication
(10) Pub. No.: US 2025/0248001 A1
(43) Pub. Date: Jul. 31, 2025

(54) FLUID HEAT DISSIPATION FLAT TUBE STRUCTURE

(71) Applicant: Jinlian Industry Hardware Co., Ltd., Zhuhai (CN)

(72) Inventor: Xiao Zeng, Zhuhai (CN)

(21) Appl. No.: 18/801,457

(22) Filed: Aug. 12, 2024

(30) Foreign Application Priority Data
Jan. 31, 2024 (CN) 2024202381488

(51) Int. Cl. H05K 7/20

(52) U.S. Cl. CPC H05K 7/20272; H05K 7/20772

(57) ABSTRACT

A fluid heat dissipation flat tube structure, comprising a flat tube structure body, L-type terminals and extending double L-shaped solder terminals, each flat tube structure body is an integrally formed structure, and the integrally formed flat tube structure body is used for fluid heat dissipation. The invention belongs to the technical field of heat dissipation of industrial equipment, specifically refers to a fluid heat dissipation flat tube structure, which can solve the problems in prior art that large area linear welding structure is prone to cause deformation of the flat tube structure, and fatigue break, cracks and leakage at the welded joint.

### 1. TECHNICAL FIELD

The invention belongs to the technical field of heat dissipation of industrial equipment, and specifically refers to a fluid heat dissipation flat tube structure.

### 2. BACKGROUND ART

Fluid cooling technology refers to, under environment of high power progress driven by artificial intelligence, new energy and other computing power enhancement and that the traditional air cooling technology can not meet the need for heat dissipation and conductive cooling of high power chips in new technical conditions, utilizing copper, aluminum, steel, high-performance plastics, and other materials with high thermal conductivity and fluid medium to absorb heat generated by source of heat, which is then transmitted to the cooling mechanism via fluid flow channel structure, circular injection after being fully cooled down to achieve the purpose of rapid heat dissipation.

Shortcomings for prior art lies in that, for a large area of linear welding structure, in the installation, transportation, testing, application process of the material, the flat tube structure is prone to deformation, whether it is deformed by external forces or deformation caused by high pressure in the chamber, it will produce stress fatigue on the strength of the welded joints and lead to leakage phenomenon; once the leakage occurs, it will cause serious losses due to short circuit and burning out of server circuit board.

### 3. SUMMARY OF THE INVENTION

In order to solve the above mentioned problems in prior art that large area linear welding structure is prone to cause deformation of the flat tube structure, and fatigue break, cracks and leakage at the welded joint, the invention provides a fluid heat dissipation flat tube structure.

In order to realize the above functions, the technical solution provided by the invention is as follows: a fluid heat dissipation flat tube structure, comprising a flat tube structure body, L-type terminals and extending double L-shaped solder terminals, each flat tube structure body is an integrally formed structure, and the integrally formed flat tube structure body is used for fluid heat dissipation.

As a preferred technical solution of the invention, said flat tube structure body is in welded connection with L-type terminals, said L-type terminals are welded to both ends of the flat tube structure body, and welded joints of said flat tube structure body and L-type terminals adopt step positioning.

As a preferred technical solution of the invention, said flat tube structure body is in welded connection with extending double L-shaped solder terminals.

Compared with the prior art, the invention has the following advantages:
1. The integrally formed flat tube structure body is used for fluid heat dissipation, and the welding process is actually local welding, different from the overall heating of the traditional flat tube welding, which reduces the phenomenon of annealing softening after flat tube being heated at high temperatures, and avoids the problem in prior art that the material is prone to become soft, easily deformed and not easy to correct shape, and brittle failure at welding joints will occur if it is forced to correct shape; the welding process does not require the flat tube structure body to be clamped and shaped and completely avoids problem of unevenness of the heat source contact surface, which is conducive to ensuring and increasing the contact area of the heat source surface of the chip to enhance heat dissipation performance of the chip, increasing the heat dissipation efficiency by 20% on the basis of original structure;
2. Welded joints of said flat tube structure body and L-type terminals adopt step positioning, L-type terminals are welded at L-type turnings at two ends of the flat tube structure body to achieve the sealing effect; welding structure adopts step positioning, which can effectively prevent risk of solder overflowing into the inner chamber, and welded with L-type terminal and separator to form the flow channel; the flat tube structure of fluid flow channel, through pre-molding to cooperate with the solder terminal and being welded into an integral structure with great gas tightness has solved the risk of welded joints leakage in long-strip welding line of traditional flat tube welding structure, so that the heat dissipation module performance has been maximized and maintained, to further enhance the service life of the server and improve the heat dissipation effect;
3. Extending double L-shaped solder terminals are used for the installation of different application scenarios, and can be combined and arranged to form different modular structures, which enhances the stability of the welding quality, and increases the life of the heat source heat dissipation module and fatigue resistance performance in actual use; it can be applied to designs of fluid heat dissipation in different scenarios and structures, and can be used for servers, personal computers, new energy vehicles, new energy energy storage, medical equipment, etc;
4. The flat tube structure body provides a direction of design for simple technological process for actual production and processing, which follows the principle of ergonomics and provides a strong guarantee in the realization of reliable and stable mass production; it can provide a full range of optimization programs according to the actual application scenarios to reduce costs and save space, etc., and it can adjust external dimensions, thickness, molding positions of the structure according to the actual application scenarios, so as to adapt to different needs of installation; it can also adjust the material, grade and state of the structure, such as: copper, stainless steel, aluminum, iron, non-metallic materials, etc., so as to meet the needs of customers for different equipment heat dissipation performances according to the actual application scenario.

### 4. BRIEF DESCRIPTION OF ACCOMPANY DRAWINGS

FIG. 1 shows an overall structural diagram of a fluid heat dissipation flat tube structure proposed in the invention;

FIG. 2 shows another overall structural diagram of a fluid heat dissipation flat tube structure proposed in the invention;

FIG. 3 shows a structural diagram of welding structure of a fluid heat dissipation flat tube structure proposed in the invention;

FIG. 4 shows a structural diagram of welding combination of a fluid heat dissipation flat tube structure proposed in the invention;

FIG. 5 shows a modular structural diagram of a combined arrangement of a fluid heat dissipation flat tube structure proposed in the invention.

FIG. 6 shows a modular structural diagram of a combined arrangement of a fluid heat dissipation flat tube structure proposed in the invention.

FIG. 7 shows a modular structural diagram of a combined arrangement of a fluid heat dissipation flat tube structure proposed in the invention.

Wherein: 1 flat tube structure body, 2 L-type terminal, 3 extending double L-shaped solder terminal.

### 5. SPECIFIC EMBODIMENT OF THE INVENTION

The technical scheme of the invention is further described clearly and detailedly hereinafter with reference to the drawings. Obviously, only partial embodiments of the invention are shown and the actual structure is not limited thereto. All other embodiments, which can be obtained by those skilled in the art without making any creative effort based on the embodiments in the present invention, shall all fall within the protective scope of the invention.

In the description of the embodiments of the invention, it should be noted that, if the terms “center”, “on”, “below”, “left”, “right”, “vertical”, “horizontal”, “inner”, “outer”, etc. indicate orientations or positional relationships based on the orientations or positional relationships shown in the drawings or the orientations or positional relationships that the products of the invention are usually placed in when used, the orientations or positional relationships are only used for convenience of describing the invention and simplifying the description, but the terms do not indicate or imply that the devices or elements indicated must have specific orientations, be constructed in specific orientations, and operate, and therefore, should not be construed as limiting the invention. Furthermore, the terms “first”, “second”, “third” and the like are used solely to distinguish one from another and are not to be construed as indicating or implying relative importance.

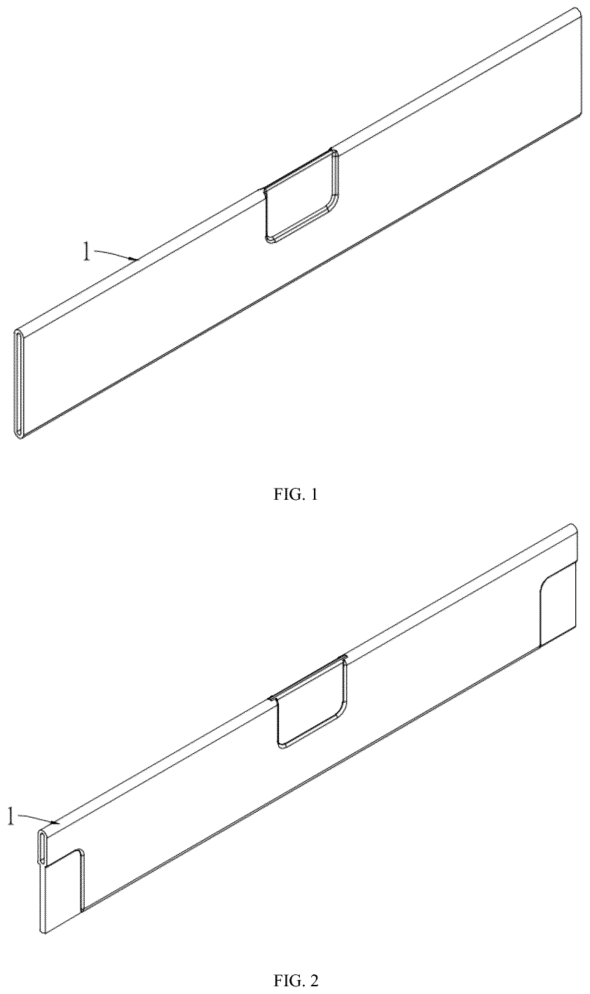

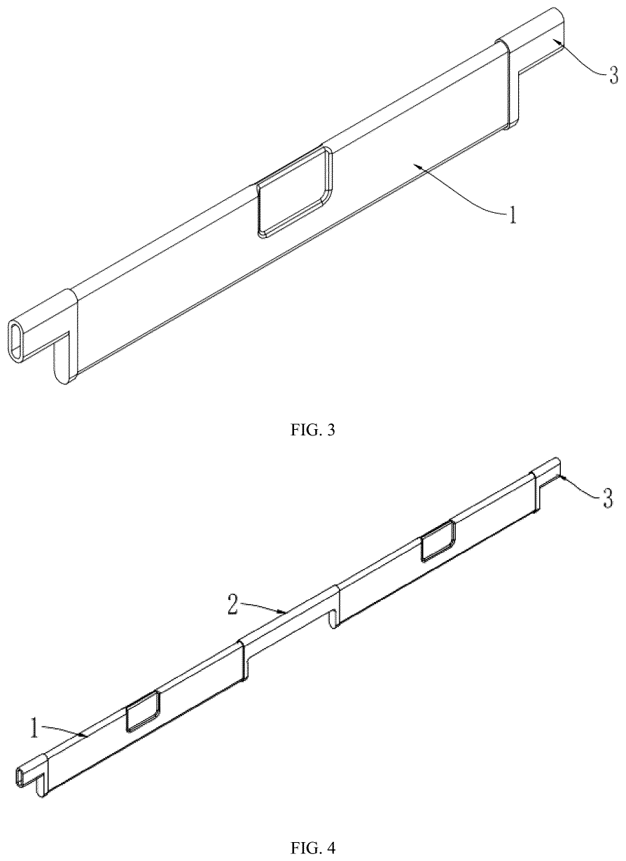

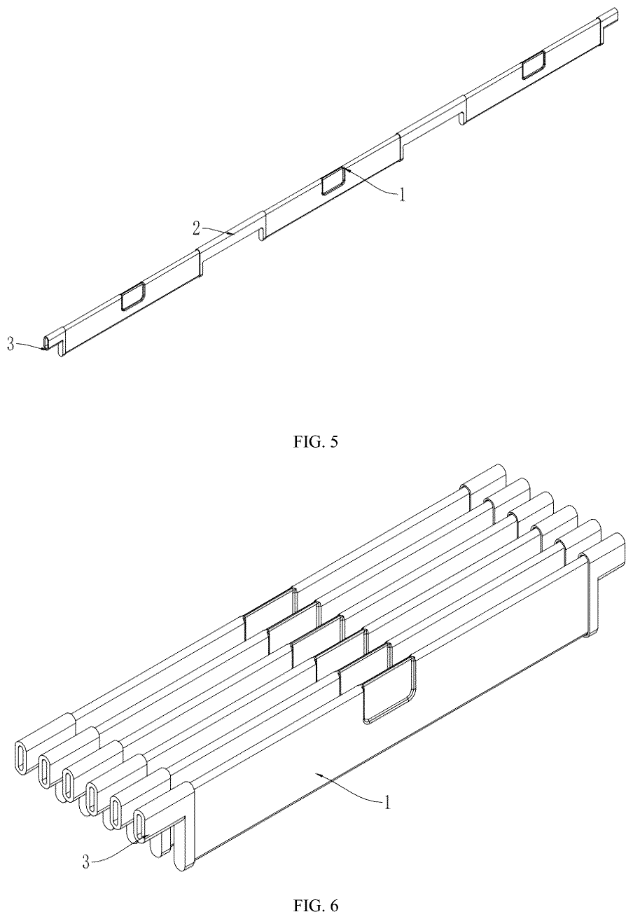

As shown from FIG. 1 to FIG. 4, the invention provides a fluid heat dissipation flat tube structure, comprising a flat tube structure body 1, L-type terminals 2 and extending double L-shaped solder terminals 3, it can adjust external dimensions, thickness, molding positions of the structure according to the actual application scenarios, so as to adapt to different needs of installation; it can also adjust the material, grade and state of the structure, such as: copper, stainless steel, aluminum, iron, non-metallic materials, etc. and different materials can be combined for molding, such as: copper+copper combination, stainless steel+stainless steel combination, aluminum+aluminum combination, copper+stainless steel combination, copper+aluminum combination, so as to meet the needs of customers for different equipment heat dissipation performances. Each flat tube structure body 1 is an integrally formed structure, and the integrally formed flat tube structure body 1 is used for fluid heat dissipation, and the welding process is actually local welding, different from the overall heating of the traditional flat tube welding, which reduces the phenomenon of annealing softening after flat tube being heated at high temperatures, and avoids the problem in prior art that the material is prone to become soft, easily deformed and not easy to correct shape, and brittle failure at welding joints will occur if it is forced to correct shape; the welding process does not require the flat tube structure body 1 to be clamped and shaped and completely avoids problem of unevenness of the heat source contact surface, which is conducive to ensuring and increasing the contact area of the heat source surface of the chip to enhance heat dissipation performance of the chip, increasing the heat dissipation efficiency by 20% on the basis of original structure.

### Embodiment 1

As shown from FIG. 1 to FIG. 2, the flat tube structure body 1 is used solely.

### Embodiment 2

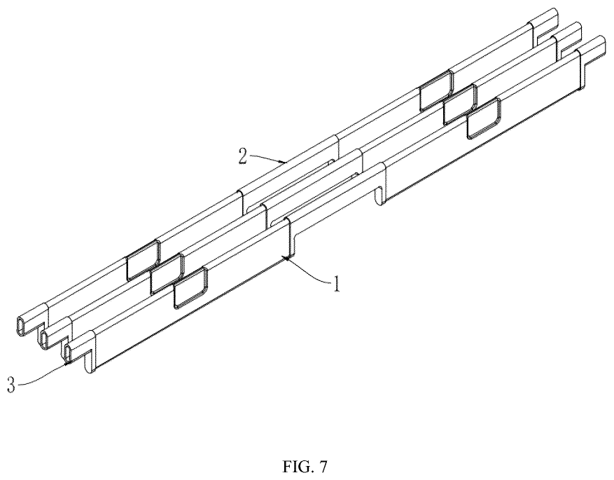

As shown from FIG. 5 to FIG. 7, the flat tube structure body 1, L-type terminals 2 and extending double L-shaped solder terminals 3 are integrated into a single unit by means of welding; said flat tube structure body 1 is in welded connection with L-type terminals 2, said L-type terminals 2 are welded to both ends of the flat tube structure body 1, and welded joints of said flat tube structure body 1 and L-type terminals 2 adopt step positioning, which can effectively prevent risk of solder overflowing into the inner chamber, and welded with L-type terminal 2 and separator to form a flow channel.

As shown from FIG. 5 to FIG. 7, said flat tube structure body 1 is in welded connection with extending double L-shaped solder terminals 3, and the extending double L-shaped solder terminals 3 can be mounted in different application scenarios.

Specifically, splicing and welding methods can be combined and arranged according to heat dissipation environment of different products, each single unit or the whole welded part has a very strong adaptive capacity, and can be applied to a plurality of continuous assembly welding function; due to the use of small end face area welding process, the welding area is reduced by more than 80% compared with prior art; and in the installation, transportation, testing, application environment, middle position, with the highest frequency of occurring deformation and leakage, achieved the state of connection with no welded joints, the strength of which is greatly enhanced and avoids the risk of leakage arising therefrom.

The invention and its embodiments have been described above, but the description is not limited thereto; only one embodiment of the invention is shown in the drawings, and the actual structure is not limited thereto. In general, it is to be understood by those skilled in the art that non-creative design of structural forms and embodiments that are similar to the technical solutions without departing from the spirit of the invention shall all fall within the protective scope of the invention.

1. A fluid heat dissipation flat tube structure, comprising a flat tube structure body, L-type terminals and extending double L-shaped solder terminals, wherein each flat tube structure body is an integrally formed structure.

2. The fluid heat dissipation flat tube structure of claim 1, wherein said flat tube structure body is in welded connection with L-type terminals, said L-type terminals are welded to both ends of the flat tube structure body.

3. The fluid heat dissipation flat tube structure of claim 2, wherein welded joints of said flat tube structure body and L-type terminals adopt step positioning.

4. The fluid heat dissipation flat tube structure of claim 1, wherein said flat tube structure body is in welded connection with extending double L-shaped solder terminals.
